(19) United States
(12) Patent Application Publication
(10) Pub. No.: US 2009/0091025 A1
(43) Pub. Date: Apr. 9, 2009

(54) METHOD FOR FORMING AND RELEASING INTERCONNECTS

(75) Inventors: Ee Hua Wong, Singapore (SG); Ranjan Rajoo, Singapore (SG); Shoa Siong Lim, Singapore (SG)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Agency for Science, Technology and Research, Singapore (SG)

(21) Appl. No.: 11/867,652

(22) Filed: Oct. 4, 2007

(51) Int. Cl. H01L 23/488; B23K 31/02; B32B 38/10

(52) U.S. Cl. 257/737; 156/247; 228/155; 257/E23.023

(57) ABSTRACT

A method for forming and releasing interconnects by using a dummy substrate. The method comprises applying metallization to the dummy substrate for creating a relatively strong bond between the metallization and the dummy substrate and a weak bond between a first end of each of the interconnects and the metallization; weakly bonding the first ends to the metallization; shaping the interconnects; releasing the weak bond between the metallization and the first ends by using a reduced release force to release the first end of the interconnects from the dummy substrate.

### TECHNICAL FIELD

This invention relates to a method for forming and releasing interconnects and more particularly, though not exclusively, relates to such a method using a dummy substrate with there being a reduced release force to release the interconnects from the dummy substrate.

### BACKGROUND

With trend towards ever finer interconnection feature size and the resultant increase in the effective stress in the interconnects, it has become increasingly challenging for interconnection to meet temperature cycling and drop-impact requirements. At the same time, the introduction of relatively delicate Cu/low-k chips imposes constraints on the level of allowable packaging stress. One solution is to increase the compliance of the interconnection so as to reduce the interconnect stress such as by, for example, using wafer-level stretched interconnections with an hourglass shape. The reliability of the stretched interconnect may be further enhanced by deforming the stretched interconnect into, for example, a spiral or stretched-spring shape.

A key challenge for wafer-level stretched interconnects is the release of the stretched interconnects from a dummy substrate without deforming the delicate, stretched solder columns, especially the stretched-spring columns; and without damaging the delicate Cu/low-k structure. The release method is also preferably capable of high-volume manufacturing while retaining a strong joint between the stretched interconnect and the substrate to which the interconnects are attached.

### SUMMARY

According to an exemplary aspect, there is provided a method for forming and releasing interconnects by using a dummy substrate, the method comprising: applying metallization to the dummy substrate for creating a relatively strong bond between the metallization and the dummy substrate and a weak bond between a first end of each of the interconnects and the metallization; weakly bonding the first ends to the metallization; shaping the interconnects; and releasing the weak bond between the metallization and the first ends by using a reduced release force to release the first end of the interconnects from the dummy substrate.

The reduced release force may be applied to a fixture attached to the dummy substrate. Brittle fracture may be created in joints between the first ends and the metallization. The fixture may be attached to the dummy substrate by at least one of: bonding, glueing, and use of a thermoplastic.

The metallization may be a combination of metallization layers on the dummy substrate. The release may be along an intermetallic boundary.

The combination of metallization layers may be applied by applying a second layer to the dummy substrate that adheres to the dummy substrate, and applying a first layer to the second layer. The first layer may provide a weak bond with the first ends and a strong bond to the second layer. The first layer may wet with the first ends of the interconnects.

A thermal oxide layer may be applied to the dummy substrate before the second layer. The thermal oxide layer may provide a relatively high strength bond with the dummy substrate. The second layer may have a relatively high strength bond with the thermal oxide layer.

Each of the first ends of the interconnects may have an effective area where they may be bonded to the metallization that may be reduced in comparison with a second end of the interconnects where the interconnects may be attached to a functional substrate.

Reinforcing may be formed around the functional substrate and the second ends. The first ends may have a reduced contact area on the metallization.

Each of the first ends of the interconnects may have a cavity after shaping the interconnects.

Each of the first ends of the interconnects may be profiled to increase the circumference-to-area ratio of each of the first ends.

The profiling of the first ends may be to form a stress riser to facilitate initiation of cracks in the first ends to assist release of the first ends from the metallization. An outer contour of each of the first ends may be maintained. An interior area of the first ends may be reduced.

The fixture may be rigid and the reduced release force may be an impact force provided on the rigid fixture.

The fixture may be flexible and the reduced release force may be applied to edges of the flexible fixture. The force may be at least one of: reciprocating, and alternating.

A plurality of vias may be formed in the dummy substrate prior to metallization. The metallization may be around the vias.

A chemical etchant may be used to perform chemical etching of the first ends through a cavity in the first ends and through the vias so as to weaken attachment of the first ends to the metallization.

According to another exemplary aspect there is provided a method for forming shaped interconnects by using a dummy substrate, the method comprising: shaping a first end of each interconnect to have a reduced contact area with the dummy substrate, the reduced contact area providing stress concentration for facilitating brittle fracture of the attachment of the first ends with the dummy substrate; weakly bonding the first ends to the dummy substrate; shaping the interconnects; releasing the weak bond between the metallization and the first ends by using a reduced release force to release the first end of the interconnects from the dummy substrate.

Each of the first ends of the interconnects may have an effective area where they may be attached to the dummy substrate that may be reduced in comparison with a second end of the interconnects where the interconnects may be attached to a functional substrate. Reinforcing may be formed around the functional substrate and the second ends.

Each of the first ends of the interconnects may be profiled to increase the circumference-to-area ratio of each of the ends. The profiling of the first ends may be to form a stress riser to facilitate initiation of cracks in the first ends to assist release of the first ends from the dummy substrate. An outer contour of each of the first ends may be maintained. An interior area of the first ends may be reduced.

A fixture may be placed over the dummy substrate and a force provided on the fixture to create brittle fracture in the joints between the first ends and the dummy substrate. The fixture may be a flexible fixture. The force may be at least one of: reciprocating, and alternating. A plurality of vias may be formed in the dummy substrate prior to attachment of the first ends.

A chemical etchant may be used to perform chemical etching of the first ends through a cavity in the first ends and through the vias to weaken attachment of the first ends to the dummy substrate.

For both aspects, after release the first ends may be bonded to a third substrate using a bonding agent. The cavity may be filled with the bonding agent during the bonding to the third substrate.

According to a further exemplary aspect there is provided a method for forming shaped interconnects by using a dummy substrate, the method comprising: profiling a first end of each of the interconnects to increase the circumference-to-area ratio of each of the first ends and to form a stress riser to facilitate initiation of cracks in the first ends to assist release of the first ends from the dummy substrate; weakly bonding the first ends to the metallization; shaping the interconnects; releasing the weak bond between the metallization and the first ends by using a reduced release force to release the first end of the interconnects from the dummy substrate.

Each of the first ends of the interconnects may have an effective area where they may be attached to the dummy substrate. The first ends may be reduced in comparison with a second end of the interconnects where the interconnects may be attached to a functional substrate. The first ends may be also shaped to have a reduced contact area with the dummy substrate. The reduced contact area may provide stress concentration for facilitating brittle fracture of the attachment of the first ends with the dummy substrate. Reinforcement may be formed around the functional substrate and the second ends. An outer contour of each of the first ends may be maintained. An interior area of the first ends may be reduced.

A rigid fixture may be placed over the dummy substrate. An impact force may be provided on the rigid fixture to create brittle fracture in the joints between the first ends and the dummy substrate.

A flexible fixture may be attached to the dummy substrate. A force may be applied to edges of the flexible fixture to create brittle fracture in the joints between the first ends and the dummy substrate. The force may be at least one of: reciprocating, and alternating.

A plurality of vias may be formed in the dummy substrate prior to attachment of the first ends. A chemical etchant may be used to perform chemical etching of the first ends through a cavity in the first ends and through the vias to weaken attachment of the first ends to the dummy substrate.

For all foregoing aspects, after release the first ends may be bonded to a third substrate using a bonding agent. The cavity may be filled with the bonding agent during the bonding to the third substrate.

According to a penultimate exemplary aspect there is provided a dummy substrate comprising at least one metallization layer having a relatively strong bond between the metallization and the dummy substrate and may be for providing a weak bond between a first end of each of a plurality of interconnects and the metallization.

The at least one metallization layer may be a combination of metallization layers on the dummy substrate. The combination of metallization layers may comprise a first layer that provides a weak bond with the first ends and a strong bond to a second layer. The second layer may have a relatively strong bond with the dummy substrate. The first layer may wet with the first ends of the interconnects. A thermal oxide layer may be between the dummy substrate and the second layer. The thermal oxide layer may provide a relatively high strength bond with the dummy substrate. The second layer may have a relatively high strength bond with the thermal oxide layer.

The dummy substrate may further comprise a plurality of vias. The at least one metallization layer may be around the vias.

According to a final exemplary aspect there is provided a package comprising a substrate and a first die connected and spaced apart by shaped interconnects formed by one of the methods given above.

The package may further comprise a second die between the substrate and the first die. The second die may be connected to the first die. The second die may be connected to the first die by connections selected from: solder balls and low temperature bonding. The second die and the first die may be connected and spaced apart by another set of shaped interconnects formed by one of the methods given above. The package may further comprise a third die between the second die and the first die. The third die may be connected to the first die by connections selected from: solder balls and low temperature bonding. The package may further comprise a second die connected to and spaced apart from the first die by another set of shaped interconnects formed by one of the methods given above. There may be a third die between the second die and the first die. The third die may be connected to the second die; and a fourth die between the first die and the substrate. The fourth die may be connected to the first die. The third die may be connected to the second die. The fourth die may be connected to the first die. Connections may be selected from: solder balls and low temperature bonding.

### BRIEF DESCRIPTION OF THE DRAWINGS

In order that the invention may be fully understood and readily put into practical effect there shall now be described by way of non-limitative example only exemplary embodiments, the description being with reference to the accompanying illustrative drawings.

In the drawings:

FIG. 1 is three illustrations that show an exemplary processes for reduced wetting area with (a) showing the interconnects attached to the dummy and functional substrates; (b) showing the interconnects after removal of the dummy substrate; and (c) showing after the third substrate is attached;

FIG. 2 is four illustrations of exemplary embodiments of reduced wetting area;

FIG. 3 is three illustrations of exemplary embodiments of high-speed releasing methods where (a) is spalling, (b) is mechanical shock, and (c) is resonant vibration;

FIG. 3A is three illustrations of an exemplary encapsulation process;

FIG. 3B is four illustrations of steps in an exemplary solder transfer and decal detachment process;

FIG. 4 illustrates five exemplary fabrication processes for reduced wetting area with through silicon via where (a) is a blanket dummy substrate, (b) is through-hole vias using RIE, (c) is thermal oxide (1000 A), (d) is splutter Cr-Au, and (e) is patterning;

FIG. 5 is an illustration of an exemplary enhanced bonding due to a cavity formed from the design with reduced interior area;

FIG. 6 is an illustration of an exemplary embodiment of a ring pad design;

FIG. 7 is an illustration of an exemplary form of a cavity created due to the ring pad design of FIG. 6;

FIG. 8 gives exemplary embodiments of joints released using high speed loading;

FIG. 9 is an illustration of an exemplary package design;

FIG. 10 is an illustration of another exemplary package design;

FIG. 11 is an illustration of a further exemplary package design; and

FIG. 12 is an illustration of yet another exemplary package design.

### DETAILED DESCRIPTION OF THE EXEMPLARY EMBODIMENTS

The exemplary embodiment relates to a method of separating a plurality of interconnects extending between two substrates. The interconnects may have been elongated or deformed into a specific shape such as, for example, hourglass and/or spiral and/or spring. Alternatively, the interconnects may not have been deformed. The interconnects may be of any suitable form including, but not limited to: hourglass, spiral, spring, post, Cu post and solder, solder only, ball, and so forth.

The substrates may be a pair of silicon wafers, a silicon wafer and a planar carrier, a plural of IC components and a planar carrier, or an IC component and a printed circuit board; and so forth.

In general, one of the substrates may contain active devices while the other may be a dummy. The dummy may be subsequently released from the interconnects.

The method may also be used in a solder transfer process to separate solder from a decal carrier after the solder has been transferred to a target structure. For the purposes of this application, the term dummy substrate is taken to include a decal carrier, while the term interconnect is taken to include solder that has bonded with the target structure.

In an exemplary case, the substrate with the interconnects may be singulated into smaller components. The smaller components may subsequently be attached to a third substrate using the released end of the interconnects. A bonding agent may be used for the attachment.

Mechanical separation offers a simple and inexpensive method of releasing the dummy substrate from the interconnects. However, the separation force is preferably minimised to prevent damage to the stretched interconnects, the substrate, and any delicate interface such as, for example, a Cu/low-k interface. This may be achieved through the use of one or more of:
(i) weaker metallization;
(ii) a reduced effective wetting/bonding area;
(iii) high-speed loading; and
(iv) a combination of chemical etching and high-speed loading.

Weak metallization is a combination of sputtered metallization layers on the dummy substrate. This creates a weak bond between the interconnects and the sputtered metallization layers. The weak bond contributes to the ease of separation of the interconnects from the dummy substrate without damage to the interconnects. The separation may be along the intermetallic boundary.

The metal layers typically consists of a first layer (or wetting layer) that wets with the interconnect solder, and a second layer (or adhesion layer) that adheres the first layer to the substrate. The detached interconnects should be able to be attached to a third substrate using a bonding agent. As such, the detached surface of the interconnects are preferably able to wet readily with the bonding agent.

A number of metallizations and thicknesses have been evaluated. For example, Cr of 200 A as an adhesion layer and Au of 500 A as wetting layer have been identified to give satisfactory results. Other suitable metals may be used. Both adhesion and wetting layer in the weak metallization may range from 0 to 500 A depending on the interconnect material used.

Described below are some exemplary methods and results for designing/selecting/verifying the weak metallization. Other methods may be used. A test specimen is shown in FIG. 6 and data provided in Table 1 below. Here, solder balls 626 are first formed on the dummy substrate 103 sputtered with the weak metallization 627. The solder balls 626 are sheared individually at a shear speed of 0.05 mm/s and the shear height is maintained at 50 μm to form solder bumps. Subsequently, the dummy substrate 103 and solder bumps 626 were bonded to a functional blank chip sputtered with conventional UBM layer. Mechanical tensile test have been performed.

TABLE 1

| Chip size | 5 mm by 5 mm |
|---|---|
| Pad size | 300 μm |
| Pitch | 600 mm |
| Number of joints | 28 |

The test matrix and the test results for the shear and pull test are tabulated in Table 2 and Table 3 respectively.

TABLE 2

| | | Solder: Sn 3.8Ag 0.7Cu | | Solder: Sn 3.0Cu | |
|---|---|---|---|---|---|
| | Thickness | Avg. Shear | Failure | Avg. Shear | Failure |
| Weak Metallization | (Å) | Strength (g) | Mode | Strength (g) | Mode |
| Chrome (Cr)/ | 200/500 | 190.43 | Cr-solder or | 189.47 | Cr-solder or |
| Gold (Au) | | | Au-solder | | Au-solder |
| | | | interface | | interface |
| Titanium (Ti)/ | 200/500 | 273.33 | Bulk | 239.16 | Bulk |
| Gold (Au) | | | | | |
| Titanium (Ti)/ | 200/500 | 266.49 | Bulk | 219.67 | Bulk |
| Copper | | | | | |
| (Cu) | | | | | |
| Nickel (Ni)/ | 200/500 | 305.96 | Bulk | 254.53 | Bulk |
| Gold (Au) | | | | | |
| Nickel (Ni)/ | 200/200 | 242.69 | Bulk | 197.20 | Bulk |
| Gold (Au) | | | | | |

TABLE 3

| | | Solder: Sn3.0Cu | |
|---|---|---|---|
| | Thickness | Avg. Tensile | |
| Weak Metallization | (Å) | Strength | Failure Mode |
| Chrome (Cr)/Gold | 200/500 | 57.20 | Cr-solder or |
| (Au) | | | Au-solder interface |
| Titanium (Ti)/Gold | 200/500 | 79.56 | Bulk |
| (Au) | | | |
| Titanium (Ti)/Copper | 200/500 | 49.42 | Bulk |
| (Cu) | | | |
| Nickel (Ni)/Gold (Au) | 200/500 | 77.04 | Bulk |
| Nickel (Ni)/Gold (Au) | 200/200 | 107.11 | Bulk |

The Cr (200 A)-Au (500 A) metallization system gave the best results in that it gave the lowest shear and pull strength; and the desired failure interface when using SnCu as the interconnect material.

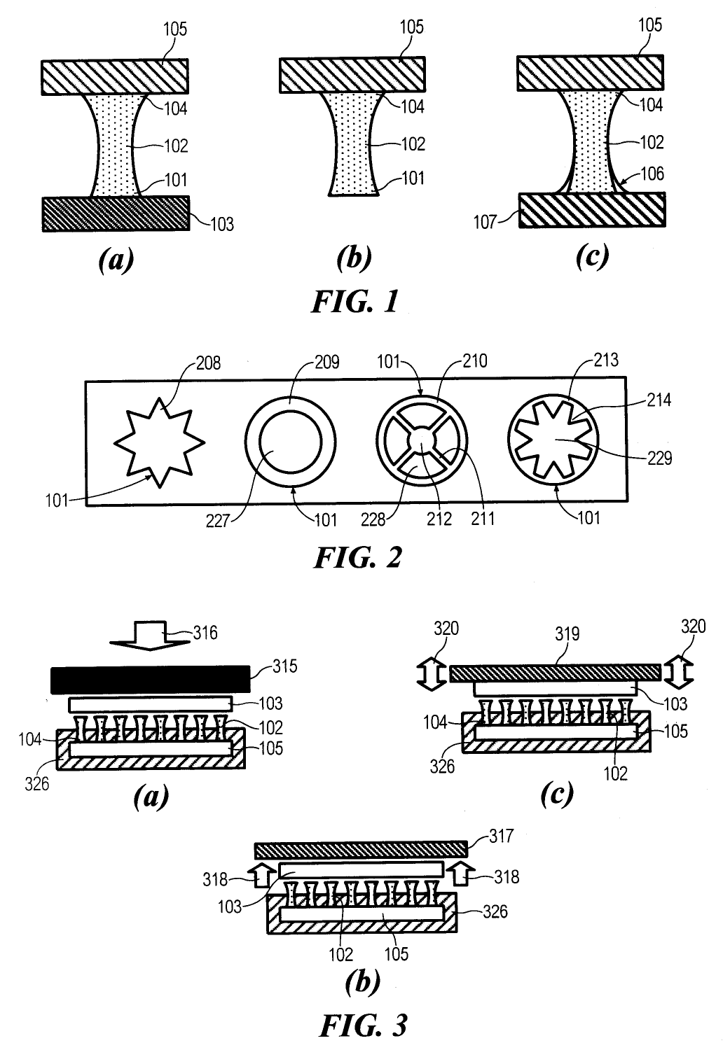

As shown in FIG. 1, due to the dummy substrate 103 having a reduced pad area design, the effective wetting/bonding area between the ends 101 of the interconnects 102 and the dummy substrate 103 may be reduced in comparison with the end 104 of the interconnects 102 where the interconnects 102 are attached to the main or functional substrate 105. The reduced pad area on the dummy substrate 103 facilitates cavity formation on the ends 101 after shaping the interconnects, which assists the accommodation of the additional volume of the bonding agent 106 when the interconnects 102 are attached to a third substrate 107.

However, excessive reduction of the area of the ends 101 may lead to poor shape formation of the interconnects 102. To address this problem, exemplary pad designs as shown in FIG. 2 are provided so as to:
(i) contour the circumference of each end 101, as shown in FIG. 2(a), where the ends have a “star” shape with radially outwardly directed triangular projections 208. The projections 208 may be of any suitable shape and are not restricted to triangular. The contour may be such that it is a stress riser to facilitate initiation of cracks for easy release from the dummy substrate 103; and/or
(ii) retain the outer contour while reducing the interior area of the ends 101 as shown in FIGS. 2(b) to (d), where:
   (b) shows an annular structure 209 with a circular unsputtered centre area 227;
   (c) shows a pad structure 210 having radial spokes 211, a central hub 212 and regions of unsputtered area 228; and
   (d) shows an annular pad structure 213 having radially-inwardly directed triangular projections 214 such that an unsputtered centre area 229 is approximately [symbol] -shaped. The projections 214 may be of any suitable shape and are not restricted to triangular.

All three examples of FIG. 2(b) to (d) reduce the effective wetting/bonding area between the ends 101 of the interconnects 102 and the dummy substrate 103. As the adhesion strength of the ends 101 of the interconnects 102 to the dummy substrate 103 is proportional to the bonding area, this reduction proportionately reduces the adhesion strength so as to facilitate separation without requiring excessive force.

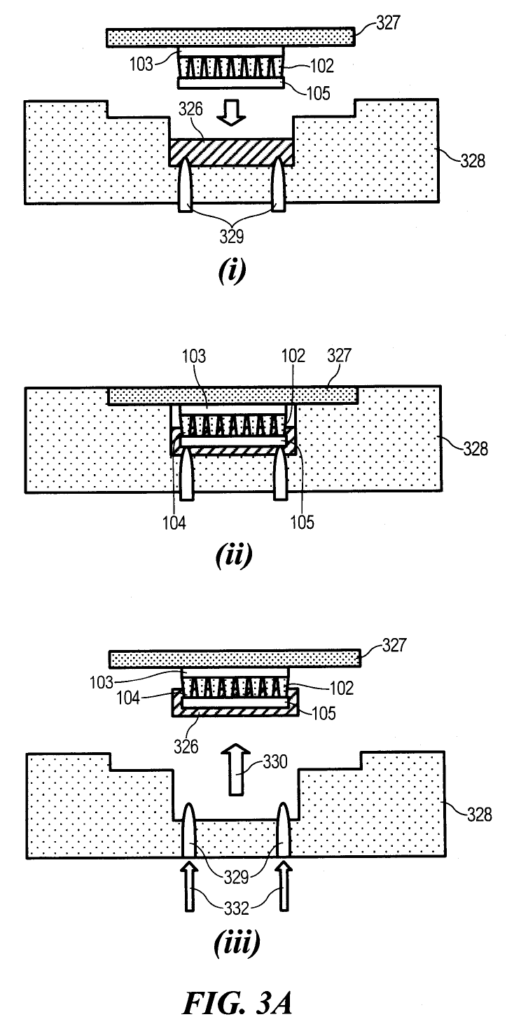

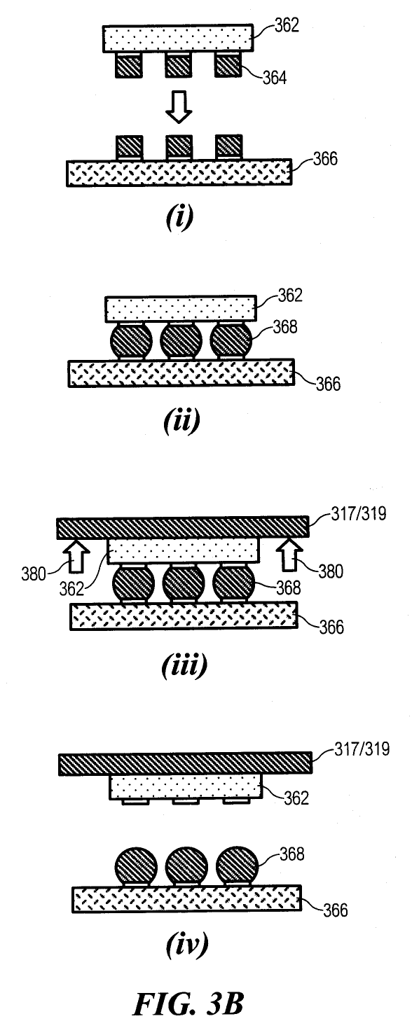

A joint between an end 101 of an interconnect 102 and the dummy substrate 103 may exhibit brittle fracture upon impact at high strain rate. As such, the strength of the joint decreases with an increase in the strain rate. Three methods of utilizing this tendency to brittle fracture for the separation of the dummy substrate 103 from the interconnects 102 are illustrated in FIG. 3. In all three examples, the assembly of FIG. 1 has been turned over so the dummy substrate 103 is on top. This may be optional. The three examples are:
(i) spalling in FIG. 3(a) where a rigid fixture 315 is attached to the dummy substrate 103 and an impact force 316 provided on the rigid fixture 315. This causes failure in the joints between the ends 101 and the dummy substrate 103 thus allowing separation;
(ii) mechanical shock in FIG. 3(b) where a flexible fixture 317 is attached to the dummy substrate 103 and a force 318 applied to the edges of the flexible fixture 317 to force the dummy substrate 103 to separate from the ends 101 of the interconnects 102. The force applied may be an impact force such as by dropping the assembly of the dummy substrate 103, interconnects 102, functional substrate 105 and the flexible fixture 317 such that the flexible fixture 317 (but not the dummy substrate 103, interconnects 102 and functional substrate 105) contacts edge stops to induce brittle fracture at the ends 101 and for thereby having ease of separation of the ends 101 from the dummy substrate 103; and
(iii) high frequency resonant vibration as illustrated in FIG. 3(c) where a flexible fixture 319 is attached to the dummy substrate 103 and an alternating or reciprocating force 320 applied to the ends of the flexible fixture 319 to break the connection between the ends 101 and the dummy substrate 103 to force the dummy substrate 103 to separate from the ends 101 of the interconnects 102. The force may be in phase at the opposite ends, or may be out of phase. If out of phase, the forces may be 180° out of phase. This may be by use of a vibrating table.

These three exemplary techniques shown in FIG. 3 introduce high strain rate to the interconnect 102. As solder interconnects have a tendency to exhibit brittle fracture when a high strain rate is applied, by applying the exemplary techniques in FIG. 3, this tendency to brittle fracture may be utilized to facilitate separation without excessive force.

These three techniques require attachment of the dummy substrate 103 to the fixture 315, 317, 319 thereby avoiding clamping stress. This may be by bonding, glueing, or use of a thermoplastic. They are also able to be used with dummy substrates 103 of any size. The methods may be performed at a wafer level.

Reinforcement 326 may be provided over the functional substrate 105 and second ends 104 as a form of strengthening of the joints between the second ends 104 and the functional substrate 105 during the detachment process. This may be by use of known encapsulation techniques. An example of an encapsulation process is shown in FIG. 3A (i) to (iii). The dummy substrate 103 is attached to a fixture 327 that acts as a support during the process. Fixture 327 may be the rigid fixture 315 or flexible fixture 317, 319 used in the above-mentioned exemplary separation techniques. A stencil 328 containing the reinforcement material 326 in a liquid or molten state is provided. The stencil 328 includes releasing pins 329 for pushing out the fixture 327 and substrates 103, 105 after the reinforcement 326 has solidified.

During the process, the fixture 327 is lowered so that the functional substrate 105 is immersed in the reinforcement material 326, as shown in FIG. 3A(ii). It is important that the reinforcement material 326 encapsulates the entire functional substrate 105. However, the interconnects 102 should only be partially encapsulated at the second ends 104. When the reinforcement material 326 has solidified, the encapsulated functional substrate 105 and second ends 104 are released in the direction shown by the arrow 330 by pushing the releasing pins 328 in the direction shown by arrows 332. Examples of reinforcement material 326 that may be used include moulding compound, underfill, flux, wax, and thermoset plastics.

Encapsulation may also help to protect the die after detachment and singulation of the functional substrate 105 into individual dies. This may improve package reliability in case of drop or temperature cycling, for example.

In an exemplary solder transfer process, to detach a decal carrier from solder that has been transferred to a target structure, the separation examples using the flexible fixtures 317 and 319 are suitable. FIG. 3B(i) shows a decal 362 carrying solder 364 and a target structure 366. Solder 364 from the decal carrier 362 is transferred to the target structure 366 using a standard solder transfer step, as shown in FIG. 3B(ii). Depending on the choice of separation technique, a flexible fixture 317 or 319 is then attached to the decal carrier 362 as shown in FIG. 3B(iii), and an appropriate force 380 is applied to the flexible fixture 317 or 319 as described above. FIG. 3B(iv) shows the decal carrier 362 successfully detached from the transferred solder 368, achieving increased solder 368 on the target structure 366.

If desired or required, chemical etching could be used before mechanical release to weaken the attachment of the interconnects 102 to the dummy substrate 103. Chemical etching is especially effective for those interconnects 102 having ends 101 with a reduced interior pad area design (e.g. as shown in FIGS. 2(b) to (d)).

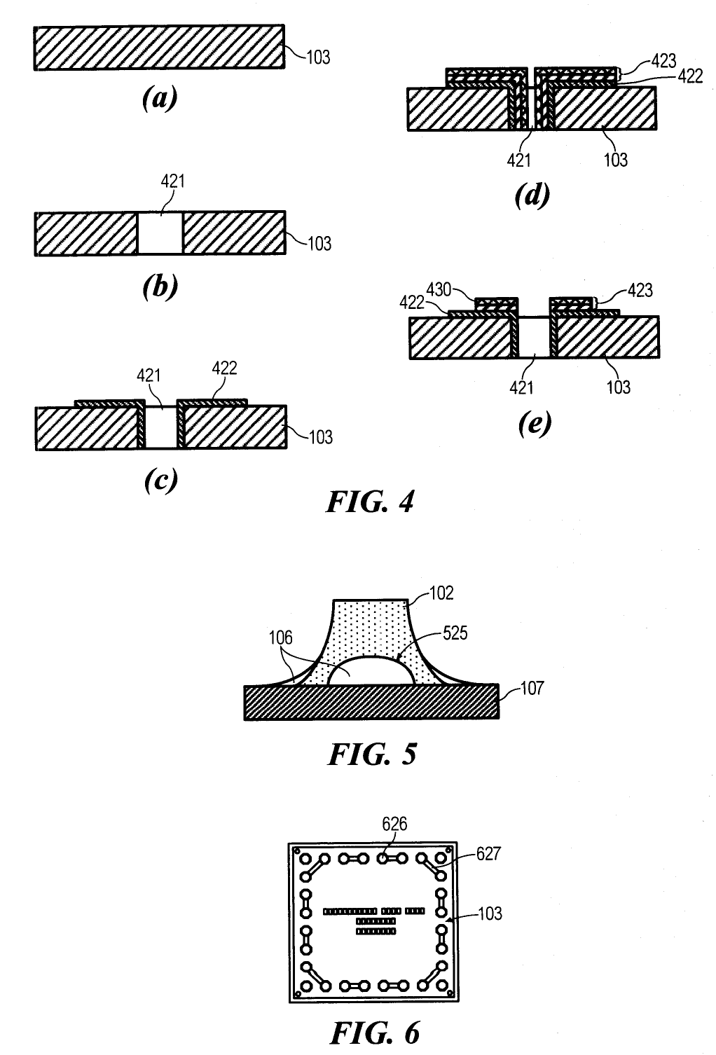

To further enhance the effectiveness of chemical etching prior to mechanical release, through vias can be fabricated on the dummy substrate 103, as shown in FIG. 4:
(a) the dummy substrate 103 is processed using RIE;
(b) to form vias 421;
(c) a thermal oxide 422 is then applied. The thermal oxide 422 may be, for example, 1000 A and provides a high bond strength with the dummy substrate 103. Then thermal oxide 422 may be considered as a bonding or seed layer;
(d) metallization layer or layers 423 such as, for example, Cr-Au layer or layers 423 may be applied by, for example, sputtering. The metallization layers 423 extend around the vias 421 and into the vias 421, but do not extend over the entire surface of the dummy substrate 103. As explained above, the metallization layers 423 provide a weakened bond between the ends 101 of the interconnects and the metallization layers 423. The metallization layers 423 have a relatively high bond strength with the dummy substrate 103; and
(e) metallization is followed by patterning 424 to reduce the area of the metallization layers 423 around the vias 421 and to remove the metallization layers 423 from within the vias 421. Patterning also provides an intermetallic boundary 430. The ends 101 of the interconnects 102 can then be bonded to the metallization layers 423 around each via 421.

The through vias 421 leading to the interior of the pad area allows the chemical etchant to reach the interior of the ends 101 through the vias 421 to pre-crack the weak metallization layers 423 so as to facilitate subsequent mechanical release.

The formation of the through vias, as shown in FIG. 4, may only be applicable in the case of pad design 2(b) and (d). However, note that the through vias are a method introduced to facilitate better chemical etching for weakening the weak metallization for easier detachment, but they are not part of the pad design as depicted in FIG. 2.

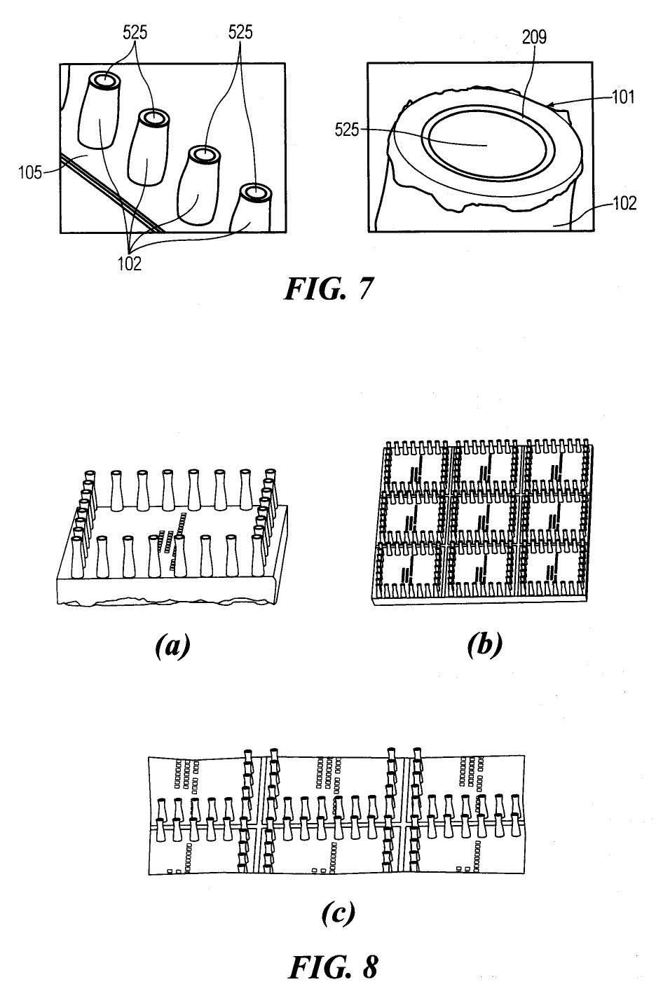

As shown in FIG. 5, the ends 101, that have an increased circumference-to-area ratio similar to those illustrated in FIG. 2(b), may result in an increased in overall surface area (inclusive of cavity 525 surface area) after solder stretching and detachment processes, and hence increased adhesion strength, when bonded to the third substrate 107. Pad designs with a reduced interior area would result in the formation of cavities in the released interconnect 102 during the solder stretching process. The cavities may be filled by the bonding agent 106 during the attachment to the third substrate 107. This will increase the bonding strength between the interconnect 102 and the third substrate 107. When the ends 101 have a ring pad form as shown in FIGS. 5 and 7, the interior area may be reduced by as much as 52% due to the cavity 525. Further experiments have yielded up to 85% reduction in area.

FIG. 8 shows the images of released joints through high speed loading (mechanical shock, resonance vibration, spalling) on:
(a) 5 mm×5 mm; and
(b) 15 mm×15 mm chips.

Release for 20 mm by 20 mm chips is achievable for aspect ratios of 2 and 3. The pad size and pitch used were 300 μm and 600 μm respectively.

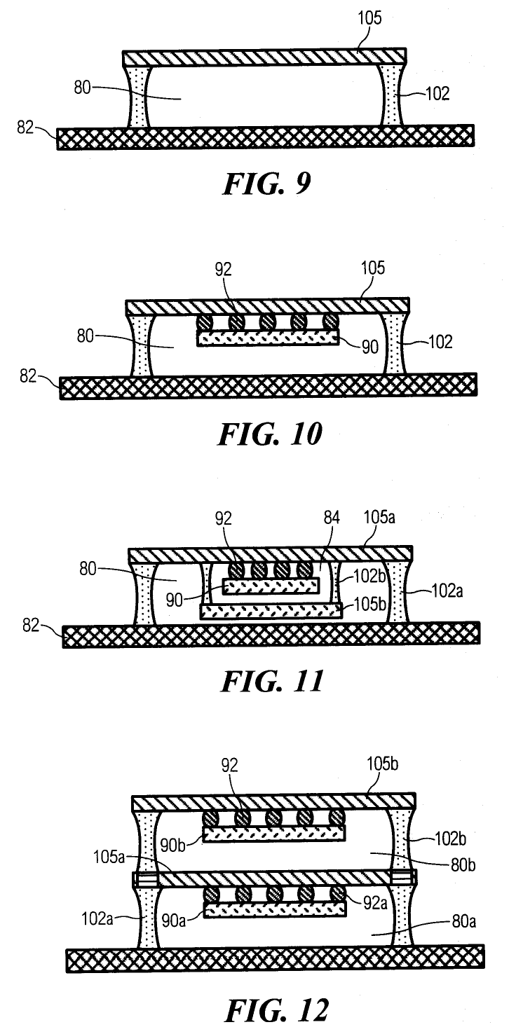

Various package designs as shown in FIGS. 9 to 12 are made possible using stretched solder interconnects formed by any of the three methods described above. FIG. 9 shows how a space 80 is created between a substrate such as a PCB 82 and a die 105. The die 105 comprises functional substrate 105 and the space 80 is a result of the high standoff provided by the stretch solders 102.

In the space 80, another die 90 can be bonded to the first die 105 using various types of interconnects, for example, the solder balls 92 shown in FIG. 10. Alternatively, low temperature bonding may be used to bond the die 90. In low temperature bonding, metals of low melting point are initially used to form bonds comprising intermetallics that have a much higher melting point so that the resultant bond remains stable during subsequent processing.

FIG. 11 shows another embodiment where a first die 105a is attached to the PCB 82 using stretched interconnects 102a to create a space 80. A second die 105b is attached to the first die 105a using stretched solders 102b to create another space 84. In the space 84, a third die 90 is bonded to the first die 105a using another interconnect 92 or using low temperature bonding.

Stacked dies may be formed as shown in FIG. 12 by having a second die 105b bonded to the top of a first die 105a that is attached to the PCB 82. In the spaces 80a, 80b created by the stretched solders 102a, 102b, further dies 90a, 90b may be respectively bonded to the first and second dies 105a, 105b using various interconnects 92a, 92b or using low temperature bonding.

The high standoff provided by the stretch solders 102 therefore provides great flexibility in package design.

Whilst there has been described in the foregoing description exemplary embodiments, it will be understood by those skilled in the technology concerned that many variations in details of design, construction and/or operation may be made without departing from the present invention.

What is claimed:

1. A method for forming and releasing interconnects by using a dummy substrate, the method comprising:
applying metallization to the dummy substrate for creating a relatively strong bond between the metallization and the dummy substrate and a weak bond between a first end of each of the interconnects and the metallization;
weakly bonding the first ends to the metallization;
shaping the interconnects; and
releasing the weak bond between the metallization and the first ends by using a reduced release force to release the first end of the interconnects from the dummy substrate.

2. A method as claimed in claim 1, wherein the reduced release force is applied to a fixture attached to the dummy substrate to create brittle fracture in joints between the first ends and the metallization; the fixture being attached to the dummy substrate by at least one selected from the group consisting of: bonding, glueing, and use of a thermoplastic.

3. A method as claimed in claim 1, wherein the metallization is a combination of metallization layers on the dummy substrate and the release is along an intermetallic boundary; the combination of metallization layers being applied by applying a second layer to the dummy substrate that adheres to the dummy substrate, and applying a first layer to the second layer, the first layer that provides a weak bond with the first ends and a strong bond to the second layer; the first layer wetting with the first ends of the interconnects and a thermal oxide layer is applied to the dummy substrate before the second layer, the thermal oxide layer providing a relatively high strength bond with the dummy substrate, and the second layer having a relatively high strength bond with the thermal oxide layer.

4. A method as claimed in claim 1, wherein each of the first ends of the interconnects has an effective area where they are bonded to the metallization that is reduced in comparison with a second end of the interconnects where the interconnects are attached to a functional substrate; reinforcing being formed around the functional substrate and the second ends and the first ends have a reduced contact area on the metallization; each of the first ends of the interconnects having a cavity after shaping the interconnects, and each of the first ends of the interconnects is profiled to increase the circumference-to-area ratio of each of the first ends; the profiling of the first ends being to form a stress riser to facilitate initiation of cracks in the first ends to assist release of the first ends from the metallization; an outer contour of each of the first ends being maintained and an interior area of the first ends is reduced.

5. A method as claimed in claim 2, wherein the fixture is rigid and the reduced release force is an impact force provided on the rigid fixture.

6. A method as claimed in claim 2, wherein the fixture is flexible and the reduced release force is applied to edges of the flexible fixture; the force being at least one selected from the group consisting of: reciprocating, and alternating.

7. A method as claimed in claim 1, wherein a plurality of vias are formed in the dummy substrate prior to metallization, the metallization being around the vias; a chemical etchant being used to perform chemical etching of the first ends through a cavity in the first ends and through the vias so as to weaken attachment of the first ends to the metallization; after release the first ends being bonded to a third substrate using a bonding agent, the cavity being filled with the bonding agent during the bonding to the third substrate.

8. A method for forming shaped interconnects by using a dummy substrate, the method comprising:
shaping a first end of each interconnect to have a reduced contact area with the dummy substrate, the reduced contact area providing stress concentration for facilitating brittle fracture of the attachment of the first ends with the dummy substrate;
weakly bonding the first ends to the dummy substrate;
shaping the interconnects; and
releasing the weak bond between the metallization and the first ends by using a reduced release force to release the first end of the interconnects from the dummy substrate.

9. A method as claimed in claim 8, wherein each of the first ends of the interconnects has an effective area where they are attached to the dummy substrate that is reduced in comparison with a second end of the interconnects where the interconnects are attached to a functional substrate; reinforcing being formed around the functional substrate and the second ends.

10. A method as claimed in claim 8, wherein each of the first ends of the interconnects is profiled to increase the circumference-to-area ratio of each of the ends; the profiling of the first ends being to form a stress riser to facilitate initiation of cracks in the first ends to assist release of the first ends from the dummy substrate.

11. A method as claimed in claim 8, wherein an outer contour of each of the first ends is maintained and an interior area of the first ends is reduced; a fixture being placed over the dummy substrate and a force provided on the fixture to create brittle fracture in the joints between the first ends and the dummy substrate.

12. A method as claimed in claim 11, wherein the fixture is a flexible fixture, and the force is at least one selected from the group consisting of: reciprocating, and alternating.

13. A method as claimed in claim 8, wherein a plurality of vias are formed in the dummy substrate prior to attachment of the first ends, a chemical etchant being used to perform chemical etching of the first ends through a cavity in the first ends and through the vias to weaken attachment of the first ends to the dummy substrate; after release the first ends being bonded to a third substrate using a bonding agent, the cavity being filled with the bonding agent during the bonding to the third substrate.

14. A method for forming shaped interconnects by using a dummy substrate, the method comprising:
profiling a first end of each of the interconnects to increase the circumference-to-area ratio of each of the first ends and to form a stress riser to facilitate initiation of cracks in the first ends to assist release of the first ends from the dummy substrate;
weakly bonding the first ends to the metallization;
shaping the interconnects; and
releasing the weak bond between the metallization and the first ends by using a reduced release force to release the first end of the interconnects from the dummy substrate.

15. A method as claimed in claim 14, wherein each of the first ends of the interconnects has an effective area where they are attached to the dummy substrate that is reduced in comparison with a second end of the interconnects where the interconnects are attached to a functional substrate; the first ends being also shaped to have a reduced contact area with the dummy substrate, the reduced contact area providing stress concentration for facilitating brittle fracture of the attachment of the first ends with the dummy substrate; reinforcement being formed around the functional substrate and the second ends and an outer contour of each of the first ends is maintained and an interior area of the first ends is reduced.

16. A method as claimed in claim 14, wherein a rigid fixture is placed over the dummy substrate and an impact force provided on the rigid fixture to create brittle fracture in the joints between the first ends and the dummy substrate.

17. A method as claimed in claim 14, wherein a flexible fixture is attached to the dummy substrate and a force applied to edges of the flexible fixture to create brittle fracture in the joints between the first ends and the dummy substrate; the force being at least one selected from the group consisting of: reciprocating, and alternating.

18. A method as claimed in claim 14, wherein a plurality of vias are formed in the dummy substrate prior to attachment of the first ends, a chemical etchant being used to perform chemical etching of the first ends through a cavity in the first ends and through the vias to weaken attachment of the first ends to the dummy substrate; after release the first ends being bonded to a third substrate using a bonding agent; the cavity being filled with the bonding agent during the bonding to the third substrate.

19. A dummy substrate comprising at least one metallization layer having a relatively strong bond between the metallization and the dummy substrate and being for providing a weak bond between a first end of each of a plurality of interconnects and the metallization.

20. A dummy substrate as claimed in claim 19, wherein the at least one metallization layer is a combination of metallization layers on the dummy substrate; the combination of metallization layers comprising a first layer that provides a weak bond with the first ends and a strong bond to a second layer, the second layer having a relatively strong bond with the dummy substrate; the first layer wetting with the first ends of the interconnects, and a thermal oxide layer is between the dummy substrate and the second layer, the thermal oxide layer providing a relatively high strength bond with the dummy substrate, and the second layer having a relatively high strength bond with the thermal oxide layer.

21. A dummy substrate as claimed in claim 19 further comprising a plurality of vias in the dummy substrate, the at least one metallization layer being around the vias.

22. A package comprising a substrate and a first die connected and spaced apart by shaped interconnects formed by the method of claim 1.

23. A package as claimed in claim 22, further comprising a second die between the substrate and the first die, the second die being connected to the first die; the second die being connected to the first die by connections selected from the group consisting of: solder balls and low temperature bonding.

24. A package as claimed in claim 23, wherein the second die and the first die are connected and spaced apart by another set of shaped interconnects formed by the method of claim 1, the package further comprising a third die between the second die and the first die, the third die being connected to the first die by connections selected from the group consisting of: solder balls and low temperature bonding.

25. A package as claimed in claim 22, further comprising a second die connected to and spaced apart from the first die by another set of shaped interconnects formed by the method of claim 1; a third die between the second die and the first die, the third die being connected to the second die; and a fourth die between the first die and the substrate, the fourth die being connected to the first die, the third die being connected to the second die and the fourth die being connected to the first die by connections selected from the group consisting of: solder balls and low temperature bonding.
